(19) United States
(12) Patent Application Publication
(10) Pub. No.: US 2006/0159133 A1
(43) Pub. Date: Jul. 20, 2006

(54) Fabricating method of semiconductor laser and semiconductor and semiconductor laser

(75) Inventors: Sun-Lyeong Hwang, Suwon-si (KR); Byeong-Hoon Park, Yongin-si (KR)

Correspondence Address: CHA & REITER, LLC, 210 ROUTE 4 EAST STE 103, PARAMUS, NJ, 07652, US

(73) Assignee: Samsung Electronics Co.; LTD

(21) Appl. No.: 11/192,891

(22) Filed: Jul. 29, 2005

(30) Foreign Application Priority Data
Jan. 19, 2005 (KR) 2005-4991

(51) Int. Cl. H01S 3/098; H01L 21/00; H01S 5/00

(52) U.S. Cl. 372/19; 438/46; 438/47; 438/39; 372/45.01; 372/46.01

(57) ABSTRACT

A method for manufacturing a semiconductor laser is provided. The method includes the steps of sequentially growing a lower clad, a lower waveguide and a multi-quantum well on a semiconductor substrate; forming, on the multi-quantum well, masks each possessing a first area which has a constant width and a second area which extends from the first area and has a gradually decreasing width, such that the masks are symmetrical to each other; sequentially growing an upper waveguide and an upper clad on the multi-quantum well through selective area growth; implementing a mesa-etching process from the upper clad to the lower clad; and growing, on the semiconductor substrate, a current blocking layer to have the same height as the upper clad.

### CLAIM OF PRIORITY

This application claims priority to an application entitled “Semiconductor laser and method for manufacturing the same,” filed in the Korean Intellectual Property Office on Jan. 19, 2005 and assigned Ser. No. 2005-4991, the entire contents of which are hereby incorporated by reference.

### BACKGROUND OF THE INVENTION

1. Field of the Invention

The present invention relates to a semiconductor laser, and more particularly, to a method for manufacturing a semiconductor laser having a mode conversion area.

2. Description of the Related Art

Recently, optical communication networks have been distributed mainly for individual subscribers. In order to provide stable optical communication service to the individual subscribers, a semiconductor laser that can stably operate and reveals a high speed modulation characteristic is demanded in the art.. Such requirements are needed even under changing environmental factors such as temperature, etc.

Many semiconductor devices are made of an InP-based compound lattice-match with quaternary materials such as InGaAsP, AlGaInAs, and the like. Most of these semiconductor devices are used as active communication devices such as optical communication semiconductor lasers, and so forth. In order to distribute the optical communication networks and satisfy these demands, semiconductor lasers mainly made of AlGaInAsP-based materials have been widely used.

Since AlGaInAsP-based materials contain a large amount of aluminum in contrast to InGaAsP-based materials problems occur when they are exposed to the atmosphere. A native oxide layer is formed to disturb re-growth of the portion under the native oxide layer. Accordingly, semiconductor lasers made of the AlGaInAsP-based material are not easy to manufacture and thus manufacturing cost increases. Methods of decreasing a mixing ratio of aluminum, etc. have been disclosed in the art as measures for solving the problems caused by the AlGaInAsP-based material.

Particular characteristic are required for semiconductor lasers used in an optical communication network. For example, high temperature, high speed operation characteristics and high optical coupling efficiency are required. A semiconductor laser in which a mode conversion area for changing a spot size is integrated has been disclosed in the art as a means for improving optical coupling efficiency

The mode conversion area is formed adjacent to an aperture through which laser light is outputted. It is formed to have vertical and lateral tapers and functions to minimize a divergence angle of the outputted light.

In a conventional semiconductor laser in which a mode conversion area is integrated, a multi-quantum well is formed through Selective Area Growth (SAG).

FIGS. 1a through 1d are views illustrating various steps of a conventional method for manufacturing a semiconductor laser. FIG. 1a is a drawing illustrating a pair of masks 101 and 102 that are formed on a semiconductor substrate 110 to be spaced apart from each other by a predetermined distance. They also have a defined symmetrical structure. FIG. 1b is a drawing illustrating a lower clad 120, a multi-quantum well 130, an upper clad 140 that are sequentially stacked upon one another on the semiconductor substrate 110 with the exception of the masks 101 and 102. Conventional semiconductor lasers can be applied in a state in which a lower waveguide (not shown) is grown on the lower clad 120 and an upper waveguide (not shown) is grown on the multi-quantum well 130.

FIG. 1c is a drawing illustrating the lower clad 120, the multi-quantum well 130 and the upper clad 140 grown in FIG. 1b are mesa-etched. FIG. 1c illustrates a stripe mask 150 that is formed on the mesa-etched upper clad 140. FIG. 1d is a drawing illustrating current blocking layers 160, 170 and 180 that are grown on the semiconductor laser mesa-etched in FIG. 1b. Thereafter, a cap 190 is grown on the current blocking layer 180.

As can be readily seen from FIGS. 1a through 1d, in the conventional art, a spot size changing effect is maximized through adopting selective area growth from the time of growing the multi-quantum well 130.

However, in the crystals of the multi-quantum well which are grown through the selective area growth, the molecules are grown while sliding on an dielectric mask surface, thus it is difficult to form crystals of high quality. As a consequence, the semiconductor laser having the multi-quantum well that is grown by the conventional method has a number of limitations. In particular, it suffers from a shortened lifetime and deteriorated reliability.

### SUMMARY OF THE INVENTION

Accordingly, the present invention has been made to reduce or overcome the above-mentioned problems occurring in the prior art. One object of the present invention is to provide a method for manufacturing a semiconductor laser, which can prevent damage to the crystals of a multi-quantum well and easily form a mode conversion area.

In accordance with the principles of the present invention a method is provided for manufacturing a semiconductor laser, including the steps of sequentially growing a lower clad, a lower waveguide and a multi-quantum well on a semiconductor substrate; forming, on the multi-quantum well, masks each possessing a first area which has a constant width and a second area which extends from the first area and has a gradually decreasing width, such that the masks are symmetrical to each other; sequentially growing an upper waveguide and an upper clad on the multi-quantum well through selective area growth; implementing a mesa-etching process from the upper clad to the lower clad; and growing, on the semiconductor substrate, a current blocking layer to have the same height as the upper clad.

### BRIEF DESCRIPTION OF THE DRAWING

The present invention will be more apparent from the following detailed description when taken in conjunction with the accompanying drawing, in which:

FIGS. 1a through 1d are views illustrating various steps of a conventional method for manufacturing a semiconductor laser;

FIGS. 2 through 8 are views illustrating various steps of a method for manufacturing a semiconductor laser in accordance with a preferred embodiment of the present invention;

FIG. 9 is a side cross-sectional view illustrating the semiconductor laser shown in FIG. 8; and

FIGS. 10a through 10c are graphs obtained by beam profile modeling of the lights radiated from semiconductor lasers manufactured under different conditions.

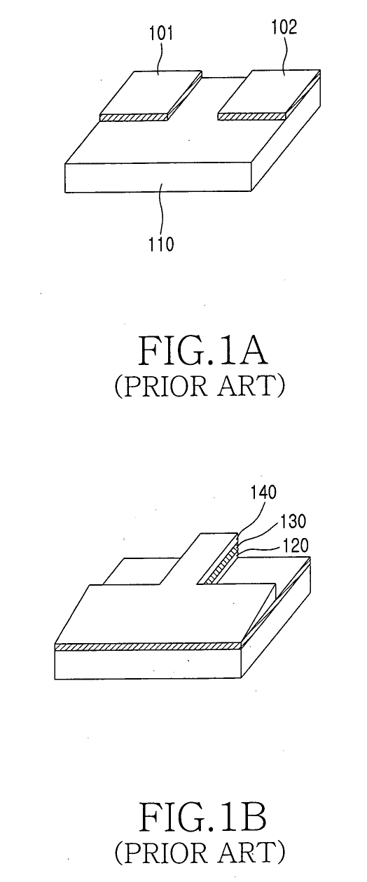

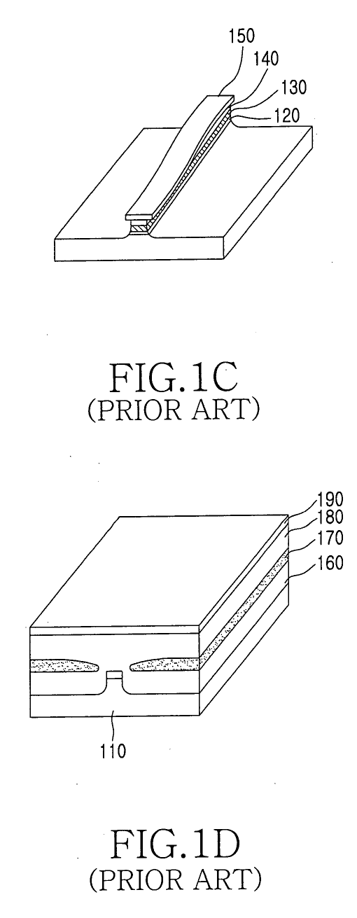

### DETAILED DESCRIPTION

Hereinafter, embodiments of the present invention will be described with reference to the accompanying drawings. In the following description, the same elements will be designated by the same reference numerals although they are shown in different drawings. Further, various specific definitions found in the following description, such as specific values of packet identifications, contents of displayed information, etc., are provided only to help general understanding of the present invention, and it is apparent to those skilled in the art that the present invention can be implemented without such definitions. For the purposes of clarity and simplicity, a detailed description of known functions and configurations incorporated herein will be omitted as it may make the subject matter of the present invention rather unclear.

FIG. 9 is a side cross-sectional view illustrating a semiconductor laser having a mode conversion area in accordance with a preferred embodiment of the present invention. Referring to FIG. 9, the semiconductor laser 200 according to the present invention includes an oscillating area 200a for producing laser-oscillated light, and a mode conversion area 200b for changing a spot size of the light produced in the oscillating area 200a.

The semiconductor laser 200 includes a lower clad 241, a lower waveguide 231, a multi-quantum well 220, an upper waveguide 232, and an upper clad 242 which are sequentially grown on a semiconductor substrate 210. The upper waveguide 232 and the upper clad 242 are grown in the mode conversion area 200b through selective area growth to have a tapered structure so that they decrease in growth thickness when measured from the multi-quantum well 220.

When the oscillating area 200a oscillates laser light having a predetermined gain, a divergence angle of the light which can be wave-guided by the upper and lower waveguides 231 and 232 varies. This is in dependence upon a growth thickness of the mode conversion area 200b measured from the multi-quantum well 220

An optical field in the mode conversion area 200b is different from that in the oscillating area 200a. Accordingly, the mode conversion area 200b minimizes the divergence angle of the light radiated from the semiconductor laser 200 by enlarging a near field of the light radiated from the oscillating area 200a.

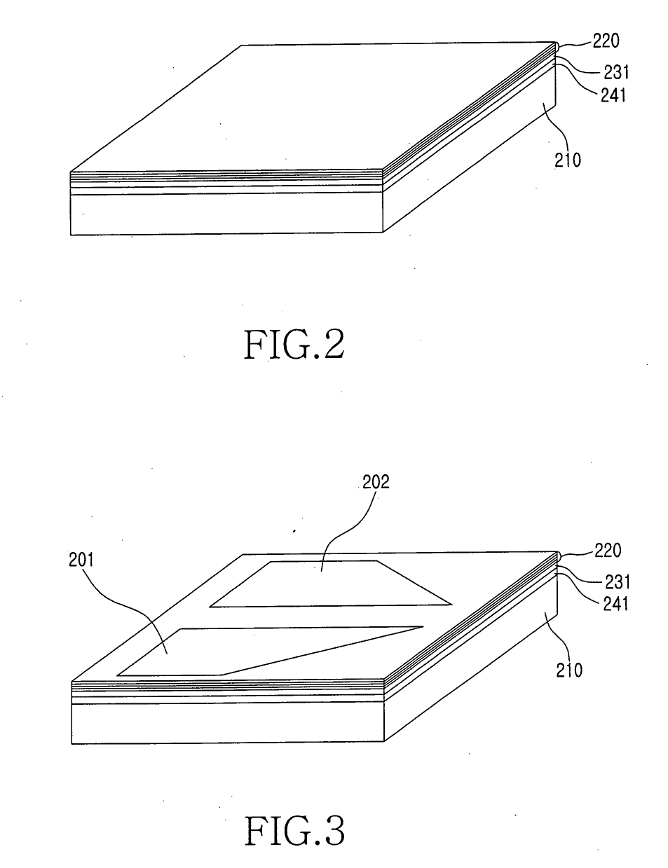

FIGS. 2 through 8 are views illustrating various steps of a method for manufacturing the semiconductor laser which is shown in FIG. 9, in accordance with a preferred embodiment of the present invention. Referring to FIGS. 2 through 8, the method for manufacturing the semiconductor laser according to the present invention includes the steps of sequentially growing the lower clad 241, the lower waveguide 231 and the multi-quantum well 220 on the semiconductor substrate 210; symmetrically forming masks 201 and 202 on the multi-quantum well 220; sequentially growing the upper waveguide 232 and the upper clad 242 through selective area growth; implementing a mesa-etching process from the upper clad 242 to the lower clad 241; growing a current blocking layer 250; and forming a cap 260 on the current blocking layer 250. In the semiconductor laser manufactured by the above-described procedure, an upper electrode (not shown) is formed on the current blocking layer 250, and a lower electrode (not shown) is formed on the lower surface of the semiconductor substrate 210.

Referring to FIG. 2, the lower clad 241, the lower waveguide 231 and the multi-quantum well 220 are sequentially grown on the semiconductor substrate 210. The lower clad 241 is grown on the semiconductor substrate 210 which is made of an InP-based material. The multi-quantum well 220 is grown using AlGaInAs-based materials.

Referring to FIG. 3, the pair of masks 201 and 202 are formed on the multi-quantum well 220 so that they define a symmetrical configuration. Each of the masks 201 and 202 possesses a first area which has a constant width and a second area which extends from the first area and gradually decreases in width. The masks 201 and 202 are formed in a manner such that they are spaced apart from each other by a predetermined distance. The masks 201 and 202 can be formed using a dielectric medium, etc. and can be made of a material such as SiO₂, etc.

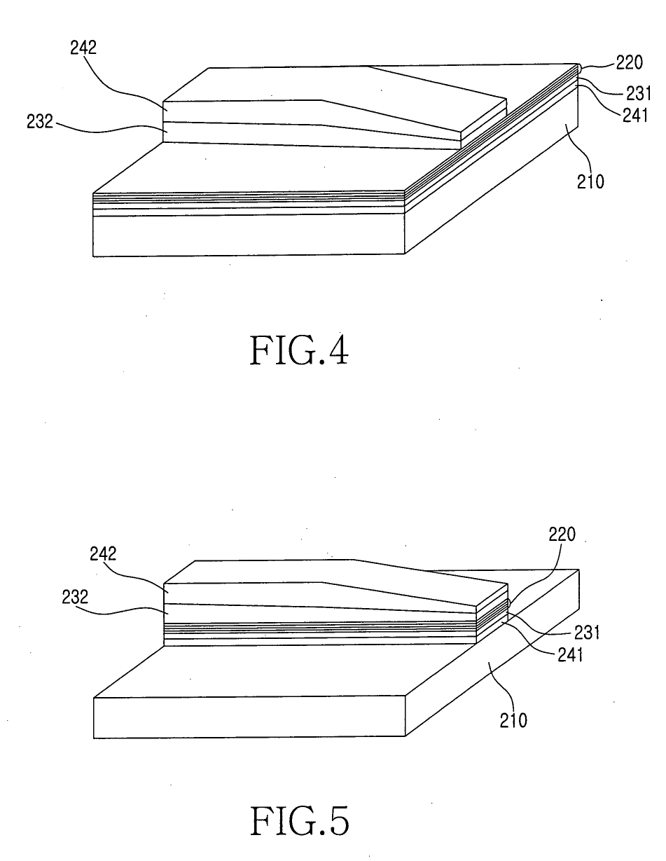

FIG. 4 is a drawing illustrating a state in which the upper waveguide 232 and the upper clad 242 are grown on the multi-quantum well 220 through selective area growth. Due to the presence of the second areas of the masks 201 and 202, one end of the upper waveguide 232 and the upper clad 242 are grown to have tapered structures. The tapered structures gradually decrease in height when measured from the multi-quantum well 220. The growth heights of the upper waveguide 232 and the upper clad 242, when measured from the multi-quantum well 220, vary in proportion to a width change in the masks 201 and 202, when assuming the same growth conditions.

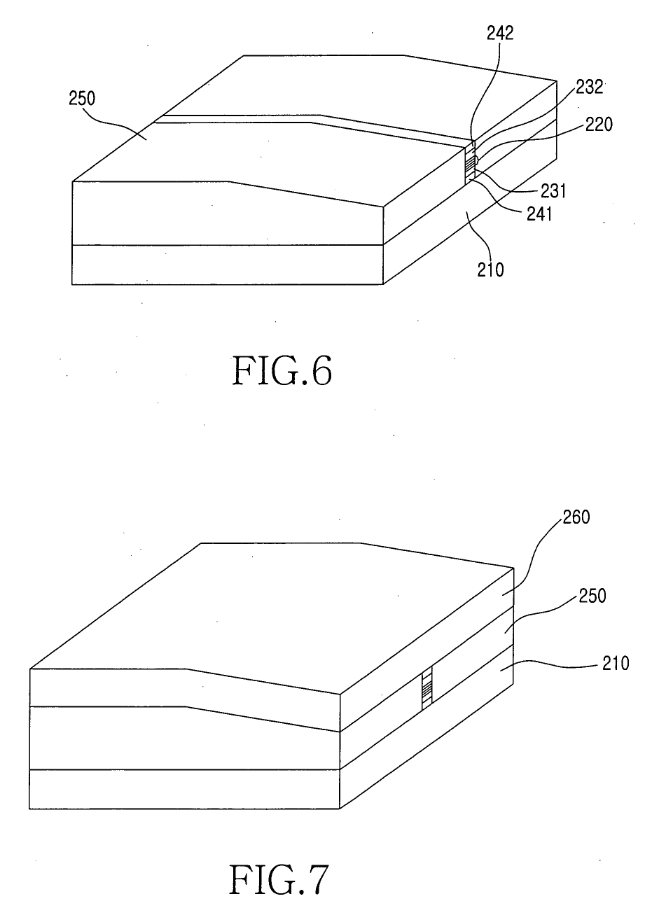

FIG. 5 is a drawing illustrating a state in which an etching process is implemented from the lower clad 241 to the upper clad 242 to define a buried hetero structure. FIG. 6 is a drawing illustrating a state in which the current blocking layer 250 is formed on the semiconductor substrate 210 at both sides of the buried hetero structure which ranges from the lower clad 241 to the upper clad 242.

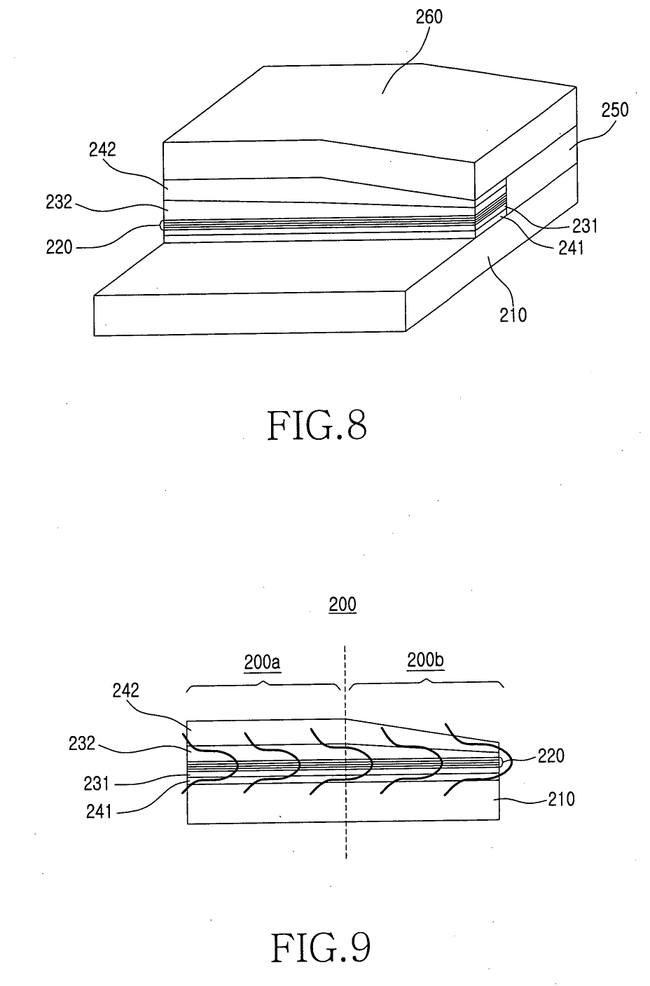

FIG. 7 is a drawing illustrating a state in which the cap 260 is grown on the current blocking layer 250. FIG. 8 is a perspective view illustrating a state in which the current blocking layer 250 and the cap 260 are partially removed.

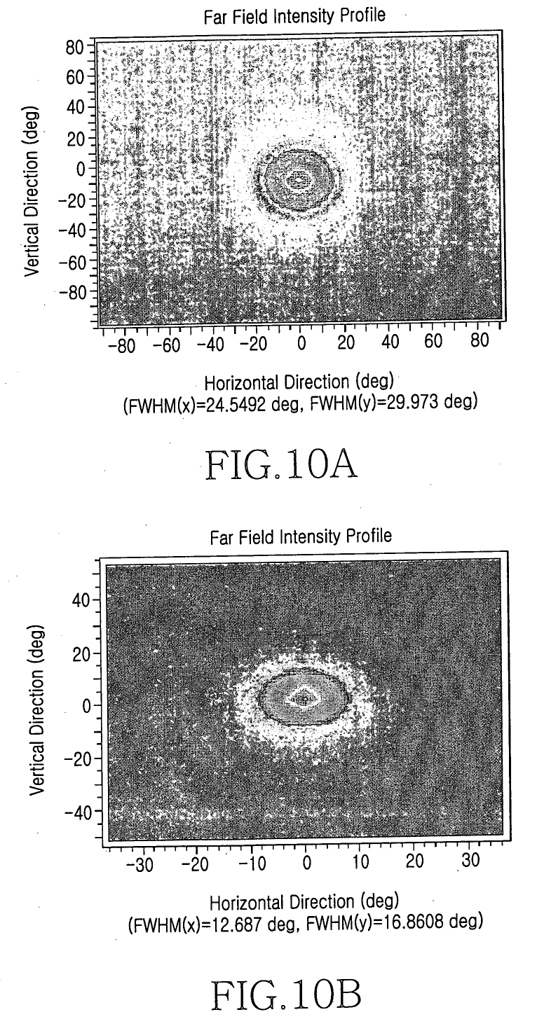

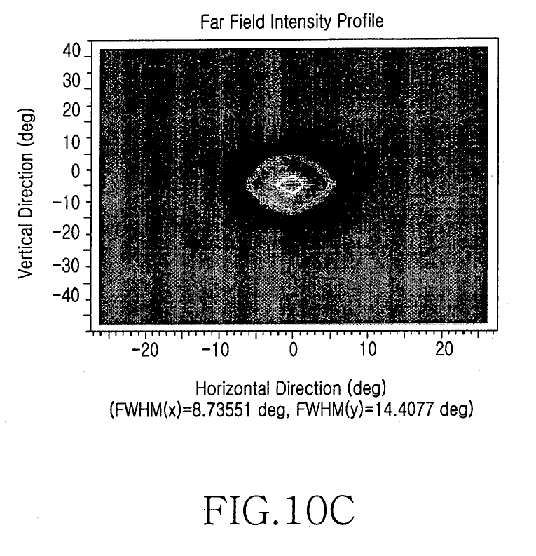

FIGS. 10a through 10c are graphs obtained through beam profile modeling of the lights radiated from semiconductor lasers manufactured under different conditions. FIG. 10a illustrates a profile of the light produced from a semiconductor laser having a known buried hetero structure. The light shown in FIG. 10a represents the profile which can be radiated at a divergence angle of 24.4×30°.

FIG. 10b illustrates a profile of the light radiated from the semiconductor laser in which a mode conversion area having a laterally tapered structure is formed by applying selective area growth to a known multi-quantum well. The light shown in FIG. 10b represents the profile which can be radiated at a divergence angle of 12.687×16.8608° which is slightly less than that of the light profile shown in FIG. 10a.

FIG. 10c illustrates a profile of the light which is produced from the semiconductor laser manufactured according to the present invention. That is to say, in the case of the semiconductor laser shown in FIG. 10c, by growing the upper waveguide and the upper clad through selective area growth, a multi-mode area is formed. The light profile shown in FIG. 10c has a divergence angle of 8.7×14.4° which is significantly reduced when compared to those of FIGS. 10a and 10b.

While the invention has been shown and described with reference to certain preferred embodiments thereof, it will be understood by those skilled in the art that various changes in form and details may be made therein without departing from the spirit and scope of the invention as defined by the appended claims.

What is claimed in:

1. A method for manufacturing a semiconductor laser, the method comprising the steps of:
sequentially growing a lower clad, a lower waveguide and a multi-quantum well on a semiconductor substrate; and
sequentially growing an upper waveguide and an upper clad on the multi-quantum well using selective area growth.

2. A method for manufacturing a semiconductor laser, the method comprising the steps of:
sequentially growing a lower clad, a lower waveguide and a multi-quantum well on a semiconductor substrate;
forming, on the multi-quantum well, at least two masks wherein the at least two masks from a symmetrical configuration;
sequentially growing an upper waveguide and an upper clad on the multi-quantum well using selective area growth;
implementing a mesa-etching process from the upper clad to the lower clad; and
growing, on the semiconductor substrate, a current blocking layer to have the same height as the upper clad.

3. The method according to claim 2, wherein the at least two masks each have a first area which has a constant width and a second area which extends from the first area and has a gradually decreasing width.

4. The method according to claim 2, further comprising:
forming a cap on the current blocking layer.

5. The method according to claim 2, wherein the upper clad and the upper waveguide are grown on a portion of the multi-quantum well, on which the at least two masks are not formed.

6. The method according to claim 2, wherein heights of the upper clad and the upper waveguide when measured from the multi-quantum well are proportional to a width of the at least two masks.

7. The method according to claim 2, wherein the lower clad is grown on the semiconductor substrate which is made of InP.

8. The method according to claim 2, wherein the multi-quantum well is grown using an AlGaInAs-based material.

9. The method according to claim 2, wherein the upper clad and the upper waveguide are grown between the first areas of the masks to have a constant height when measured from the multi-quantum well.

10. The method according to claim 2, wherein the upper clad and the upper waveguide are grown between the second areas of the masks to have a tapered structure which decreases in height when measured from the semiconductor substrate.

11. The method according to claim 2, wherein the masks on the multi-quantum well are spaced apart from each other by a predetermined distance.

12. The method according to claim 2, wherein the mesa-etching process from the lower clad 241 to the upper clad 242 forms a buried hetero structure.

13. A semiconductor laser comprising: a lower clad, a lower waveguide, a multi-quantum well, an upper waveguide and an upper clad on a semiconductor substrate, wherein the upper waveguide and the upper clad are on the multi-quantum well, and portions of the upper waveguide and the upper clad have tapered structures which gradually decrease in height when measured from the multi-quantum well.

14. The semiconductor laser according to claim 13, wherein the semiconductor laser comprises:
an oscillating area for oscillating laser light, the oscillating area including the upper waveguide and the upper clad which have predetermined heights when measured from the multi-quantum well,; and
a mode conversion area for changing a spot size of the laser light, the mode conversion area extending from the oscillating area and including the upper waveguide and the upper clad have tapered structures.
